(19) United States
(12) Patent Application Publication
(10) Pub. No.: US 2015/0259197 A1
(43) Pub. Date: Sep. 17, 2015

(54) PROCESS FOR HYBRIDIZING BY ADHESIVE BONDING TWO MICROELECTRONIC ELEMENTS

(71) Applicants: Commissariat à l'Energie Atomique et aux Energies Alternatives, Paris (FR); RENAULT s.a.s., Boulogne Billancourt (FR)

(72) Inventors: Bertrand Chambion, Saint Martin d'Heres (FR); Alexis Bedoin, Saint Victor Sur Loire (FR)

(73) Assignees: Commissariat à l'Energie Atomique et aux Energies Alternatives, Paris (FR); RENAULT s.a.s., Boulogne Billancourt (FR)

(21) Appl. No.: 14/643,411

(22) Filed: Mar. 10, 2015

(30) Foreign Application Priority Data
Mar. 11, 2014 (FR) 1451996

(51) Int. Cl. B81C 1/00

(52) U.S. Cl. CPC B81C 1/00341; B81C 2203/032

(57) ABSTRACT

The process for hybridizing a first microelectronic element (100) with a second microelectronic element (200) comprises moving the first and second microelectronic elements closer to generate an adhesive bond via interaction of first and second components (104, 202) of a two-component adhesive. At least one first member (103) and at least one second member (201) extends from said first and from second elements, respectively, the first and second components of the two-component adhesive being associated with said first and with said second elements, respectively. The first and second components are mixed via said at least one first and second members during the step of moving closer, and at the end of the step of moving closer the distance separating the first and second microelectronic elements is smaller than the cumulative height of said at least one first member and of said at least one second member before the movement closer.

### TECHNICAL FIELD OF THE INVENTION

The invention relates to the field of microelectronics and more particularly to the hybridization of two microelectronic elements at least one of which preferably comprises an electronic chip.

The subject of the invention is more particularly a process for hybridizing a first microelectronic element with a second microelectronic element, at least one first member extending from said first microelectronic element, a first component of a two-component adhesive being associated with said first microelectronic element, at least one second member extending from said second microelectronic element, a second component of the two-component adhesive being associated with said second microelectronic element, said process comprising a step of moving the first and second microelectronic elements closer such as to generate an adhesive bond via interaction of the first and second components of the two-component adhesive.

### Prior Art

In the field of microelectronics, it is commonplace to have to hybridize two separate carriers preferably at least one of which integrates an electronic chip.

The hybridization of two carriers must be improved in terms of robustness so as to prevent any separation of the latter. In this regard, it is known to make an adhesive bond.

Such a hybridizing process, employing adhesive bonding, is described in document EP 0 982 385. In this document, a substrate is equipped with electrodes intended to be connected to pads of a functional component. Before assembly of the substrate with the functional component, the electrodes are covered with a first component of a two-component adhesive and the pads are covered with a second component of the two-component adhesive. During assembly, the substrate and the functional element are moved closer such that the first and second components of the two-component adhesive interact with each other to fasten the assembly.

### SUMMARY OF THE INVENTION

The aim of the present invention is to provide a solution allowing the quality of the adhesive bond to be improved in terms of robustness and/or reliability.

This aim is at least partially achieved in that the process comprises a step of mixing the first and second components implemented via said at least one first and second members during the step of moving closer, and in that at the end of the step of moving closer the distance separating the first microelectronic element from the second microelectronic element is smaller than the cumulative height of said at least one first member and of said at least one second member before the movement closer.

Preferably, the step of moving closer is stopped when the ratio of the distance separating the first and second microelectronic elements to the cumulative height of said at least one first member and said at least one second member before the movement closer is lower than 0.9 and preferably comprised between 0.1 and 0.9.

According to one method of implementation, said at least one first member being covered with the first component and/or said at least one second member being covered with the second component, the process comprises a step of inserting said at least one first member into said corresponding at least one second member, or said at least one second member into said corresponding at least one first member, said inserting step being carried out during the step of moving closer.

According to one embodiment, the process comprises a step of electrically connecting said at least one first member with said at least one second member implemented via the inserting step, preferably said at least one first member being electrically connected to at least one electronic chip of the first microelectronic element.

Advantageously, at least one of the first or second members comprises a hollow body filled with the corresponding component of the adhesive, and the process comprises a step of expelling at least one portion of said corresponding component of the adhesive out of the hollow body implemented during the inserting step.

Preferably, the first microelectronic element comprises a plurality of first members covered with the first component and the second microelectronic element comprises a plurality of second members covered with the second component, and the mixing step is such that the first and second components mix by forced flow of the latter through obstacles formed by the first members and the second members.

Furthermore, the process may comprise a heating step implemented before or during the step of moving closer and configured so as to modify the viscosity of the first component and/or of the second component.

Preferably, the process comprises a step of forming the first component and a step of forming the second component.

The step of forming the first component may comprise:
a step of forming a mixture of said first component with a solvent that is inert with respect to said first component;
a step of depositing the mixture on the first microelectronic element; and
a step of evaporating the solvent contained in the deposited mixture.

The step of forming the second component may comprise:
a step of forming a mixture of said second component with a solvent that is inert with respect to said second component;
a step of depositing the mixture on the second microelectronic element; and
a step of evaporating the solvent contained in the deposited mixture.

The evaporating step may be implemented via a thermal cycle applied to the deposited mixture.

### BRIEF DESCRIPTION OF THE DRAWINGS

Other advantages and features will become more clearly apparent from the following description of particular embodiments of the invention, said embodiments being given by way of nonlimiting example and shown in the appended drawings, in which:

FIG. 1 is a cross-sectional view of a first microelectronic element and of a second microelectronic element before hybridization;

FIG. 2 shows a variant of FIG. 1;

FIG. 3 illustrates a cross-sectional view of the elements in FIG. 1 once hybridized;

FIG. 4 shows FIG. 2 in a hybridization configuration;

FIG. 5 shows a cross-sectional view of one particular way of hybridizing a first microelectronic element with a second microelectronic element;

FIG. 6 shows the shapes adopted by a first member and a second member; and

FIG. 7 illustrates one variant of FIG. 2.

### DESCRIPTION OF PREFERRED EMBODIMENTS OF THE INVENTION

The hybridization process differs from the prior art in that it is implemented in such a way as to promote the mixing of the two components of the two-component adhesive.

The expression “hybridization process” is understood to refer to hybridization in its broadest sense i.e. it is a question of uniting two separate elements that are, for example but not only, produced in different technologies, especially to form a unitary system.

As illustrated in FIG. 1, the process allows a first microelectronic element 100 to be hybridized with a second microelectronic element 200.

The expression “first microelectronic element and second microelectronic element” is broadly understood to mean any type of element all or some of which is produced using the techniques of microelectronics.

One and/or other of the microelectronic elements 100, 200 may be equipped with an electronic chip 101.

The expression “electronic chip” is especially understood to mean an integrated circuit for example produced using the technologies of microelectronics or even nanoelectronics.

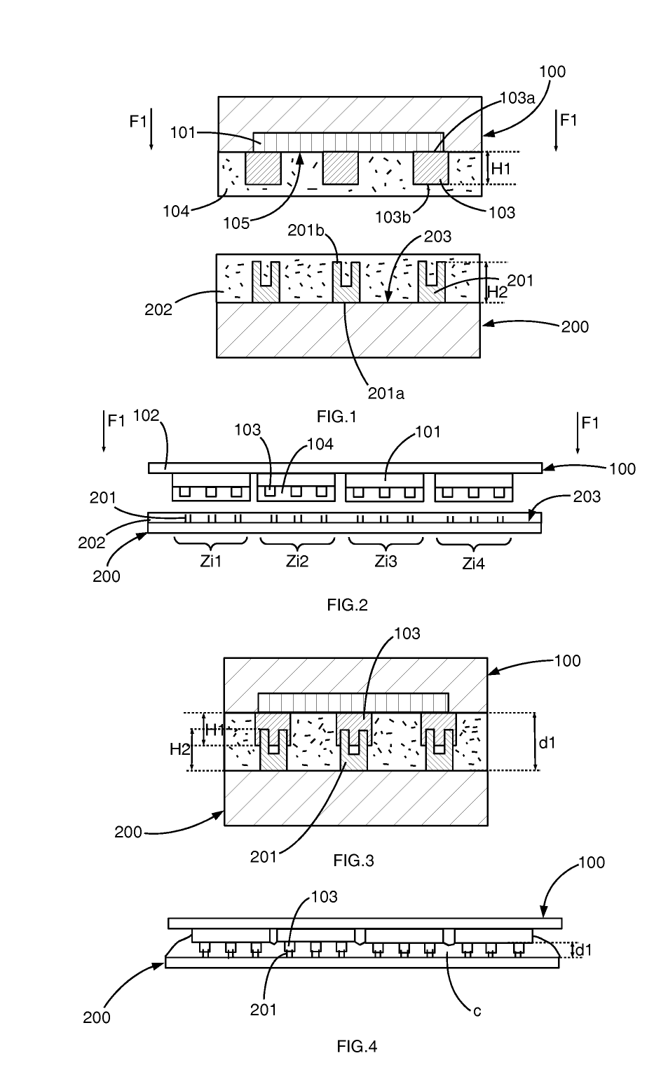

By way of example, the first microelectronic element 100 may consist of the electronic chip 101 or, as in FIG. 2, be comparable to a silicon wafer comprising a plurality of electronic chips 101, whether singulated or not. In FIG. 2, the second microelectronic element 200 will allow each of one or more electronic chips 101, especially belonging to the first microelectronic element 100, to be hybridized.

When the electronic chips 101 are not singulated, they are all integrated into a carrier such as a wafer, or even into a panel in the field of displays.

When the electronic chips are singulated (FIG. 2), the first microelectronic element 100 may comprise a film 102 to which all the electronic chips are securely fastened, especially by adhesive bonding. The film is generally adhesively bonded to a back side of a wafer before the chips are diced, the dicing of the chips allowing them to be singulated.

Generally, at least one first member 103 extends from said first microelectronic element 100 and a first component 104 of a two-component adhesive is associated with said first microelectronic element 100. At least one second member 201 extends from said second microelectronic element 200, and a second component 202 of the two-component adhesive is associated with the second microelectronic element 200.

Preferably, a plurality of first members 103 extend from the first microelectronic element 100. In the present description, everything that applies to one first member 103 may also apply to each of the first members 103. Analogously, a plurality of second members 201 may extend from the second microelectronic element 200, and everything that applies in the present description to one second member 201 may apply to each of the second members 201.

The notion of association of the first component 104 with the first microelectronic element 100 has a broad meaning. This association may be such that the first component 104 covers said at least one first member 103, especially all or part thereof, and/or the first microelectronic element 100, especially at a face 105 of said first microelectronic element 100 from which said at least one first member 103 extends.

The notion of association of the second component 202 with the second microelectronic element 200 also has a broad meaning. This association may be such that the second component 202 covers said at least one second member 201, especially all or part thereof, and/or the second microelectronic element 200, especially at a face 203 of said second microelectronic element 200 from which said at least one second member 201 extends.

Furthermore, the process comprises a step of moving (in the direction of the arrows F1) the first and second microelectronic elements 100, 200 closer such as to generate an adhesive bond via interaction of the first and second components 104, 202 of the two-component adhesive. Furthermore, the process comprises a step of mixing the first and second components 104, 202, implemented via said at least one first and second members 103, 201 during the step of moving closer.

It will be understood here that, the interaction between the first and second members 103, 201 (with or without contact of the latter) during the movement closer is such that it causes a forced flow of said first component 104 and/or said second component 202. The mixing of the first and second components 104, 202 of the two-component adhesive is improved as a result of this flow.

In particular, here the interaction of the first and second components does not occur in planes and the robustness of the adhesive bond is increased as a result. To obtain this result, it is preferable for the heights of said at least one first member and said at least one second member to be substantially equal. The expression “substantially equal heights” is understood to mean that the heights are preferably equal to within 20%, thus preventing a simple lateral flow of one of the first and/or second components of the two-component adhesive, and promoting the mixing. In other words, said at least one first member 103 being covered with the first component 104 and/or said at least one second member 201 being covered with the second component 202, said at least one first member 103 and said at least one second member 201 have heights that are substantially equal before the step of moving closer.

In fact, said at least one first member 103 and said at least one second member 201 allow asperities to be formed that will purposely participate in the mixing of the first and second components 104, 202 of the two-component adhesive during the step of moving closer. Thus, during the step of moving closer, the first member 103 will preferably constrain laterally the flow of the first component 104, and the second member 201 will preferably constrain laterally the flow of the second component 202 of the two-component adhesive. The lateral constraint is given in a flow direction substantially perpendicular (i.e. perpendicular to plus or minus 20%) to the direction of extension of the first and second members from the first microelectronic element and the second microelectronic element, respectively. Here, the directions of extension of the first and second members are oppositely oriented in the step of moving closer.

To obtain optimised mixing, at the end of the step of moving closer illustrated in FIGS. 3 and 4, the distance dl separating the first microelectronic element 100 from the second microelectronic element 200 is smaller than the cumulative height of said at least one first member 103 and said at least one second member 201 before the movement closer. The cumulative height corresponds to the sum of the heights H1 of the first member 103 and H2 of the second member 201 shown in FIGS. 1 and 3. The height H1 of the first member 103 is given in the direction in which said first member 103 extends from the first microelectronic element 100. Analogously, the height H2 of the second member 201 is given in the direction in which said second member 201 extends from the second microelectronic element 200. Thus, it will be understood that each first member 103 comprises two opposite ends 103a, 103b (FIG. 1) between which the first member 103 extends. A first end 103a of the first member 103 is located at the interface of the first member 103 with the first microelectronic element 100, and a second end 103b of the first member 103 is distant from the first microelectronic element 100 (H1 then being the distance between the ends 103a and 103b). Likewise, each second member 201 comprises two opposite ends 201a, 201b between which the second member 201 extends. A first end 201a of the second member 201 is located at the interface of the second member 201 with the second microelectronic element 200, and a second end 201b of the second member 201 is distant from the second microelectronic element 200 (H2 then being the distance between the ends 201a and 201b).

As may be seen in FIGS. 3 and 5, it is also possible, at the end of the step of moving closer, for the distance dl separating the first microelectronic element 100 from the second microelectronic element 200 to be smaller than the cumulative height of said at least one first member 103 and said at least one second member 201 after and before the movement closer. It will be understood here that the cumulative height of said at least one first member 103 and said at least one second member 201 may be different, or not, before and after the step of moving closer. This covers both the case where said at least one first member 103 is inserted into said at least one second member 201, or vice versa, and the case where two longitudinal segments belonging to said at least one first member and said at least one second member, respectively, end up facing.

To describe the mechanism in greater detail, the zones to be bonded of the first and second microelectronic elements 100, 200 are placed facing each other before the first microelectronic element 100 is moved closer with the second microelectronic element 200. In this phase, if the first and/or second members 103, 201 are covered with a component of the adhesive or with the mixture of one component of the adhesive, this component or this adhesive mixture may be removed already. In the case where the adhesive is removed, it should be noted that the flow may be likened to a plane/plane flow. The first and second components 104, 202 mix only superficially at the interface between these first and second components 104, 202. During the movement closer, the spacing between the first and second microelectronic elements reaches a value h_t, where h_t equals the sum of the height H1 of said at least one first member 103 plus the height H2 of said at least one second member 201. When the spacing is equal to h_t, the volume of the two components of the adhesive present and remaining between the members is called the passive volume. This volume is said to be passive in so far as it is yet to participate in the mixing and therefore in the adhesive bonding. This passive volume will become active, in so far as it will participate in the mixing and thus in the adhesive bonding, when enough force is applied to one of the first or second microelectronic elements 100, 200 to decrease the spacing between the first microelectronic element 100 and the second microelectronic element 200. The plane/plane adhesive flow mode that was possible before is now no longer possible as the flow of the initially passive volume is constrained. The adhesive mixes by flowing between the members.

More particularly, the step of moving closer is stopped when the ratio of the distance dl separating the first and second microelectronic elements 100, 200 to the cumulative height (H1+H2) of said at least one first member 103 and said at least one second member 201 before the movement closer is, preferably, lower than 0.9, and for example comprised between 0.1 and 0.9.

According to a first embodiment illustrated in FIG. 5, the first and second components are mixed without contact between said at least one first member 103 and at least one second member 201. In this respect, after the movement closer, adjacent first and second members 103, 201 are separated by the adhesive C. More particularly, the first member 103 comprises a segment that extends from its second end 103b in the direction of its first end 103a, and that is placed facing a segment of the adjacent second member 201, extending from its second end 201b in the direction of its first end 201a. These two segments are substantially parallel to each other and perpendicular to a plane parallel to the planes P1 and P2 containing the first microelectronic element 100 and the second microelectronic element 200, respectively (in FIG. 5, the planes P1 and P2 are perpendicular to the plane in which the figure is drawn).

In this first embodiment, according to one improvement, at least one electrical connection is formed between the first microelectronic element and the second microelectronic element (improvement not shown in FIG. 5). This electrical connection may be formed by said at least one first member (or at least one of the first members), which then makes electrical contact with a metallized receiving land of the second microelectronic element (the receiving land is then separate from the second members) at the end of the step of moving closer, or by said at least second member (or at least one of the second members), which then makes electrical contact with a metallized receiving land of the first microelectronic element (the receiving land is then separate from the one or more first members) at the end of the step of moving closer. In this respect, this improvement disassociates the mixing function assigned to the interaction between the first member(s) and the second member(s) with the first and second components of the adhesive. For example, the one or more metallized lands discussed in the present paragraph are conductive tracks formed on one portion of the microelectronic element in question (the first or the second). In this respect, the process may comprise a step of electrically connecting the first and second microelectronic elements by bringing said at least one first member into electrical contact with a metallized receiving land of the second microelectronic element and/or by bringing said at least one second member into electrical contact with a metallized receiving land of the first microelectronic element.

According to a second embodiment (FIGS. 1 and 3) the first and second components are mixed with contact between said at least one first member 103 and at least one second member 201. In this respect, the process comprises a step of inserting (FIG. 2) said at least one first member 103 into said corresponding at least one second member 201, or said at least one second member 201 into said corresponding at least one first member 103. This insertion is carried out during the step of moving closer. This insertion makes it possible to promote movement of the first and second components 104, 202 of the two-component adhesive, and therefore their mixing. In the second embodiment, said at least one first member 103 and/or at least one second member 201 are covered, especially completely or partially, by the first component 104 and the second component 202, respectively.

In particular, when one of the members 103, 201 must be inserted into another, one of them preferably has a higher ductility than the other, this makes it possible to prevent the members from breaking during the insertion step.

For example, to promote mixing of the first component and second component, in the context of insertion of one of the members 103, 201 into another member 201, 103, it is preferable for the insertion depth to be larger than 1 μm. The insertion depth is defined here as the difference between the cumulative heights of the first and second members and the final distance d1 between the two microelectronic elements 100, 200. The step of moving closer may then be stopped when the insertion depth is reached.

In certain applications, the first microelectronic element 100, especially the electronic chip 101 of the first microelectronic element 100, may make electrical contact with the second microelectronic element 200, for example with a conductive track of the second microelectronic element. In this respect, the process advantageously comprises a step of electrically connecting said at least one first member 103 to said at least one second member 201, implemented via the insertion step, said at least one first member 103 preferably being electrically connected to said corresponding at least one electronic chip 101 of the first microelectronic element 100. It will be understood here that all or some of each of said at least one first member 103 and at least one second member 201 is electrically conductive. The insertion then allows a satisfactory contact to be made between a pair comprising a first member 103 and a second member 201 such as to ensure the sought-after electrical conduction. Said at least one second member 201 may then be electrically connected to a device of the second microelectronic element 200, this device possibly being another electronic chip, or a network of electrically conductive tracks.

Again with the aim of improving mixing during the step of moving closer, at least one of the first or second members 103, 201 comprises a hollow body (in the particular example of FIGS. 1 and 3, it is the second body 201) filled with the corresponding component (the second component 202 in the example) of the adhesive (first component if the hollow body belongs to the first member, or second component if the hollow body belongs to the second member). The process then comprises a step of expelling at least some of said corresponding component of the adhesive out of the hollow body employed in the insertion step. This expulsion makes it possible to improve the mixing of the first and second components 104, 202 of the two-component adhesive.

The hollow body may be a tube having an aperture at that end of the member which is distant from the element from which said member extends.

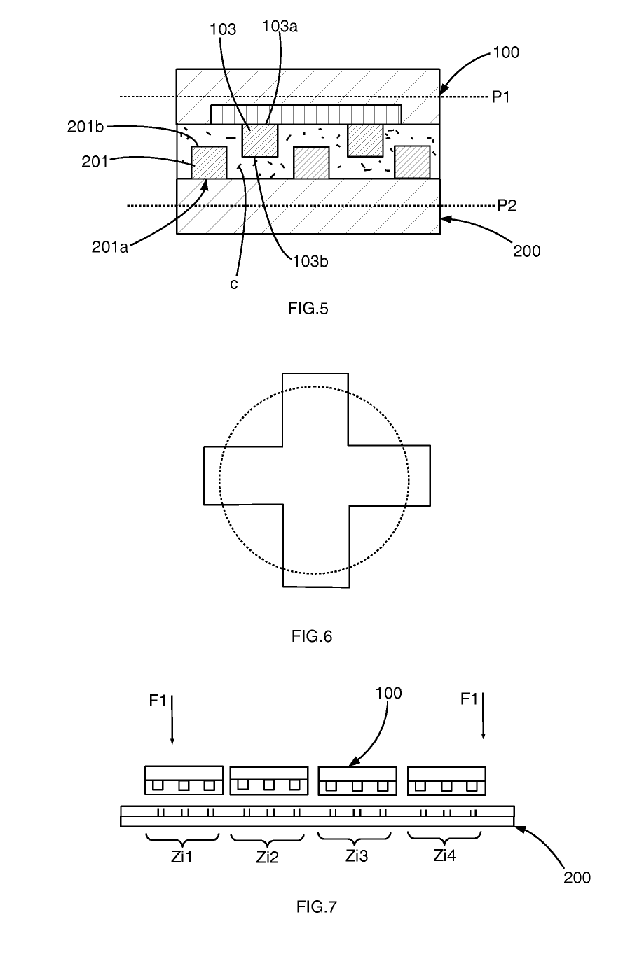

In order to make implementation of the expulsion possible, throughout the movement closer the aperture of the hollow body is preferably not blocked by the other member. Thus, the insertion is such that the pressure in the hollow body increases so as to allow the corresponding component to be expelled through said not-blocked aperture. The hollow body may be any shape that allows this expulsion to take place. FIG. 6 especially illustrates a hollow member having a cross section, perpendicular to its direction of extension relative to the element from which it extends, the general profile of which is a closed cross-shaped line. The other, preferably solid, member which is intended to interact with the member the cross section of which is cross-shaped, then has a cross section (shown by the dotted lines) the size of which is smaller than that of the cross-shaped member.

Alternatively, the first and second microelectronic elements 100, 200 are aligned so that the axes of the first and second members 103, 201 that are intended to interact with each other are offset so that the one or more hollow bodies are not blocked during the movement closer.

Preferably and applicable to everything that was said above, the first microelectronic element 100 comprises a plurality of first members 103 covered with the first component 104 and the second microelectronic element 200 comprises a plurality of second members 201 covered with the second component 202. The mixing step is such that the first and second components 104, 202 mix by forced flow (thus producing a micromixture) through obstacles formed by the first members 103 and second members 201.

In particular, to promote the mixing, at least three microstructures extend from the first microelectronic element, and at least three microstructures extend from the second microelectronic element. These microstructures will be used as mixers. Typically, three first members form the three microstructures associated with the first microelectronic element and three second members form the three microstructures associated with the second microelectronic element. For each of the first and second microelectronic elements, a local zone is defined as the zone containing at least three of these microstructures. In the case where the assembly contains more than three microstructures used as mixers, the local zone is not uniquely defined. Each local zone respects the following equation:

eA_{—}i+eB_{—}i>h_{—}f,

where eA_i; eB_i and h_f are defined in the local zone by:
eA_i: the initial average thickness of the first component in the case where the latter takes the form of a continuous film. In the case where the film is discontinuous, eA_i is defined as the initial average thickness that a continuous film of the same volume would have.
eB_i: the initial average thickness of the second component in the case where the second component takes the form of a continuous film. In the case where the film is discontinuous, eB_i is defined as the initial average thickness that a continuous film of the same volume would have.
h_f: spacing between the first and second microelectronic elements after assembly (i.e. after the movement closer).

According to one embodiment, the process comprises a heating step carried out during (or before) the step of moving closer, and configured so as to modify the viscosity of the first component 104 and/or second component 202. This modification of the viscosity especially allows the first component 104 and/or second component 202 of the two-component adhesive to be fluidified so as to improve the mixing. Those skilled in the art will be able to determine the temperature required depending on the components of the two-component adhesive.

The first component 104 may take the form of a continuous or discontinuous film formed on that face 105 of the first microelectronic element 100 from which said at least one first member 103 extends. The same goes for the second component 201, which may take the form of a continuous or discontinuous film formed on that face 203 of the second microelectronic element 200 from which said at least one second member 201 extends (FIG. 1).

Since the first microelectronic element 100, and the second microelectronic element 200 are obtained by microelectronic fabrication techniques, it was necessary to develop techniques allowing the first component 104 and the second component 202 to be formed without damaging the associated element.

In this respect, the process may comprise a step of forming the first component 104 and a step of forming the second component 202.

In particular, the step of forming the first component 104 comprises: a step of forming a mixture of said first component 104 with a solvent that is inert with respect to said first component 104; a step of depositing the mixture on the first microelectronic element 100; and a step of evaporating the solvent contained in the deposited mixture. Alternatively, the deposition may be carried out by evaporation. The solvent described here may be optional.

According to one particular embodiment, the first component 104 is a catalyst of the two-component adhesive. In this case, the step of forming the first component 104 is preferably such that the catalyst is mixed with a solvent chosen such that said catalyst is soluble in this solvent. The solution obtained is preferably deposited by spraying on the first microelectronic element 100, and in particular on the first microelectronic element 100 comprising a plurality of electronic chips. Although this deposition method is preferred, other types of deposition methods may be envisaged, such as spin coating, screen printing, inkjet printing, drop coating, lamination, etc. The deposited thickness varies depending on the percentage by volume of solvent in the solution and on deposition parameters (time, scan speed and frequency, rotation speed). The thickness range encountered in printing extends from 1 μm to 50 μm. The inkjet or screen-printing technique allows 1 μm to 10 μm to be deposited. The thickness typically deposited for a microelectronic hybridization application conventionally varies between 1 μm and 3 μm.

Similarly, the step of forming the second component 201 comprises: a step of forming a mixture of said second component 202 with a solvent that is inert with respect to said second component 202; a step of depositing the mixture on the second microelectronic element 200; and a step of evaporating the solvent contained in the deposited mixture. Alternatively, the deposition may be carried out by evaporation. The solvent described here may be optional.

In the context where the first component 104 is the catalyst discussed above, the second component 202 is the resin. In this case, the step of forming the second component 202 is preferably such that the resin is mixed with a solvent chosen such that said resin is soluble in this solvent and such that the reactive functions of the epoxy chains are not affected thereby. The solution obtained is preferably deposited by spin coating on the second microelectronic element 200. Although this deposition method is preferred, other types of deposition methods may be envisaged, such as spray coating, screen printing, inkjet printing, drop coating, lamination, etc. The deposited thickness varies depending on the percentage by volume of solvent in the solution and on deposition parameters (time and rotation speed). The thickness typically deposited varies between 1 μm and 3 μm but may be much larger. The thickness range encountered in printing extends from 1 μm to 50 μm. The inkjet or screen-printing technique allows 1 μm to 10 μm to be deposited. The thickness typically deposited for a microelectronic hybridization application conventionally varies between 1 μm and 3 μm.

By way of example, in the above description the first component 104 was the catalyst and the second component 202 was the resin. Of course, the inverse is also possible.

The evaporating step may be implemented via a thermal cycle applied to the deposited mixture. The expression “thermal cycle” is understood to mean supplying heat in such a way as to accelerate the evaporation reaction of the solvent. For example, the thermal cycle is such that the first microelectronic element 100 and the second microelectronic element 200 are placed in a chamber (separately or together) at 80° C. for 30 min.

The advantage of these steps of forming the first component and second component is that the first microelectronic element and the second microelectronic element may then be stored for a substantial amount of time before being used (i.e. before the step of moving closer such as described above is carried out).

In the product obtained using the process described above a better homogenization of the adhesive is observed on the perimeter of the layer than at its centre, this having the effect of reinforcing peripheral adherence between components.

According to one embodiment, the second microelectronic element 200 comprises a plurality of hybridization zones Zi1, Zi2, Zi3, Zi4 (FIG. 7).

Each hybridization zone Zi1, Zi2, Zi3, Zi4 is intended to receive one unitary element playing for example the role of first microelectronic element 100 and preferably comprising a single electronic chip. In this case, the process comprises a step of associating a plurality of first elements 100 with one and the same second microelectronic element 200, for example using a “pick and place” method. Each first microelectronic element 100 is such as described above, and the step of moving closer (for example in the direction of the arrows F1) will result in each first microelectronic element 100 being hybridized with the associated second microelectronic element 200, in such a way as described above. The step of moving closer may or may not be implemented concomitantly for each of the first elements 100.

Alternatively, the second microelectronic element 200 comprises a plurality of hybridization zones Zi1, Zi2, Zi3, Zi4 (FIG. 2). Each hybridization zone Zi1, Zi2, Zi3, Zi4 is intended to receive a unitary element of an element 100 comprising optionally singulated electronic chips. Each unitary element here preferably comprises a single electronic chip.

As generally applicable to everything that was said above, after the step of moving closer, the process may comprise a step of curing the mixture of the first and second components 104, 202 of the two-component adhesive. This step may be carried out at room temperature (i.e. at 25° C., for example for a suitable length of time, typically from 2 hours to 72 hours), or by implementing a step of baking the mixture of the first and second components 104, 202. The bake consists in curing the two-component mixture by creating a solid three-dimensional molecular network. Regarding the temperature values associated with given times, this varies depending on the reference of the adhesive used. The bake may be carried out using various known means such as a hot plate or oven.

According to one improvement, it is possible to remove those segments of first component and/or second component that have not mixed and that are not located between a first microelectronic element and a second microelectronic element. Typically, in the embodiment in which the first elements are formed by singulated electronic chips hybridized to one and the same second microelectronic element, the first microelectronic element is covered with unreacted second component between two electronic chips. In this respect, a simple solvent clean may allow the segments of second component located between two adjacent hybridized chips on the same first microelectronic element to be removed.

The adhesive described above may be an epoxy adhesive. In the case of an epoxy, the ratio of the volume of the first component to the second component is preferably close to 1 (it may however be as high as 1:100).

It was mentioned above that the first component 104 and/or the second component 202 may take the form of a continuous or discontinuous film. In the case where the ratios of the volumes of the first component 104 and the second component 202 would otherwise be too high (for example 1:10 or 1:20), the component having the lowest volume need not form a continuous layer.

According to one very particular embodiment, the height of each first member forming a pad is 2.5 μm and the height of each second member forming a hollow tube is 2.1 μm. Preferably, the pads and tubes are arranged in a matrix with a pitch of 10 μm, the matrix containing 320×250 connections (larger or smaller matrices, for example 640×500, 150×120, 15×20, etc. may also be imagined). The force applied during the movement closer is about 0.5 g/connection. A cumulative height of 2.5+2.1=4.6 μm and a distance d1 of 3 μm is obtained, i.e. a ratio of 0.65 in this case.

According to another very particular embodiment, the height of each first member forming a pad is 2.6 μm and the height of each second member forming a hollow tube is 2.8 μm. Preferably, the pads and tubes are arranged in a matrix with a pitch of 10 μm, the matrix containing 320×250 connections (larger or smaller matrices, for example 640×500, 150×120, 15×20, etc. may also be imagined). The force applied during the movement closer is about 1 g/connection. A cumulative height of 2.6+2.8=5.4 μm and a distance d1 of 4.8 μm is obtained, i.e. a ratio of 0.88 in this case.

Each of the chips may comprise a light-emitting diode. By virtue of this process, it becomes easy to form robust display panels equipped with a plurality of light-emitting diodes. According to another embodiment, each of the chips may be of the type used in the high-density field (a microcontroller for example) or in the field of power chips. According to one example, a chip used in the context of the invention would allow a modulation circuit for controlling (GaN) power transistors to be placed as near as possible to a power junction, in particular for a motor power-supply application.

According to one particular embodiment, the teachings of patent application FR 2 977 370 may be applied. In this case, one of said at least one first member or at least one second member is a pad and the other of said at least one first member or at least one second member is an insert such as described in said patent application FR 2 977 370.

Moreover, regarding the aforementioned insertion using a hollow body and allowing the expelling step to be carried out, the teachings of document FR 2 949 171 may advantageously be used.

According to one variant, said at least one first member and/or said at least one second member deform, especially buckle, during the step of moving closer. In this case, the member 103 is not inserted into the member 201 (or vice versa), one instead causing the other to deform during the step of moving closer.

1. Process for hybridizing a first microelectronic element with a second microelectronic element, at least one first member extending from said first microelectronic element, a first component of a two-component adhesive being associated with said first microelectronic element, at least one second member extending from said second microelectronic element, a second component of the two-component adhesive being associated with said second microelectronic element, said process comprising:
moving the first and second microelectronic elements closer such as to generate an adhesive bond via interaction of the first and second components of the two-component adhesive, and
during the step of moving the first and second microelectronic elements closer, mixing the first and second components implemented via said at least one first and second members,
wherein, at the end of the step of moving the first and second microelectronic elements closer, a distance separating the first microelectronic element from the second microelectronic element is smaller than a cumulative height of said at least one first member and said at least one second member before the first and second microelectronic elements are moved closer.

2. Process according to claim 1, wherein the step of moving the first and second microelectronic elements closer is stopped when a ratio of the distance separating the first and second microelectronic elements to the cumulative height of said at least one first member and said at least one second member before the first and second microelectronic elements are moved closer is lower than 0.9.

3. Process according to claim 1, wherein at least one of (i) said at least one first member is covered with the first component and (ii) said at least one second member is covered with the second component, and wherein the process comprises inserting said at least one first member into said corresponding at least one second member, or said at least one second member into said corresponding at least one first member, said inserting step being carried out during the step of moving the first and second microelectronic elements closer.

4. Process according to claim 3, wherein the process comprises electrically connecting said at least one first member with said at least one second member implemented via the inserting step.

5. Process according to claim 3, wherein at least one of the first or second members comprises a hollow body filled with the corresponding component of the adhesive, and wherein the process comprises expelling at least one portion of said corresponding component of the adhesive out of the hollow body implemented during the inserting step.

6. Process according to claim 1, wherein the first microelectronic element comprises a plurality of first members covered with the first component and the second microelectronic element comprises a plurality of second members covered with the second component, and wherein in the mixing step, the first and second components mix by forced flow of the first and second components through obstacles formed by the first members and the second members.

7. Process according to claim 1, wherein the process comprises, before or during the step of moving the first and second microelectronic elements closer, heating so as to modify a viscosity of at least one of (i) the first component and (ii) the second component.

8. Process according to claim 1, wherein the process comprises forming the first component and forming the second component.

9. Process according to claim 8, wherein the step of forming the first component comprises:
forming a mixture of said first component with a solvent that is inert with respect to said first component;
depositing the mixture on the first microelectronic element; and
evaporating the solvent contained in the deposited mixture.

10. Process according to claim 8, wherein the step of forming the second component comprises:
forming a mixture of said second component with a solvent that is inert with respect to said second component;
depositing the mixture on the second microelectronic element; and
evaporating the solvent contained in the deposited mixture.

11. Process according to claim 9, wherein the evaporating step is implemented via a thermal cycle applied to the deposited mixture.

12. Process according to claim 1, wherein, at the end of the step of moving the first and second microelectronic elements closer, the distance separating the first microelectronic element from the second microelectronic element is smaller than the cumulative height of said at least one first member and said at least one second member after the first and second microelectronic elements are moved closer.

13. Process according to claim 1, wherein at least one of (i) said at least one first member is covered with the first component and (ii) said at least one second member is covered with the second component, and wherein said at least one first member and said at least one second member have heights that are substantially equal before the step of moving the first and second microelectronic elements closer.

14. Process according to claim 1, wherein the process comprises electrically connecting the first and second microelectronic elements by at least one of (i) bringing said at least one first member into electrical contact with a metallized receiving land of the second microelectronic element and (ii) bringing said at least one second member into electrical contact with a metallized receiving land of the first microelectronic element.

15. The process according to claim 10, wherein the evaporating step is implemented via a thermal cycle applied to the deposited mixture.

16. The process according to claim 2, wherein the ratio of the distance separating the first and second microelectronic elements to the cumulative height of said at least one first member and said at least one second member before the first and second microelectronic elements are moved closer is between 0.1 and 0.9.

17. The process according to claim 4, wherein said at least one first member is electrically connected to at least one electronic chip of the first microelectronic element.

18. The process according to claim 4, wherein at least one of the first or second members comprises a hollow body filled with the corresponding component of the adhesive, and wherein the process comprises expelling at least one portion of said corresponding component of the adhesive out of the hollow body implemented during the inserting step.

19. The process according to claim 2, wherein at least one of (i) said at least one first member is covered with the first component and (ii) said at least one second member is covered with the second component, and wherein the process comprises inserting said at least one first member into said corresponding at least one second member, or said at least one second member into said corresponding at least one first member, said inserting step being carried out during the step of moving the first and second microelectronic elements closer.

20. The process according to claim 19, wherein the process comprises electrically connecting said at least one first member with said at least one second member implemented via the inserting step.
